(19) United States
(12) Patent Application Publication
(10) Pub. No.: US 2011/0129954 A1
(43) Pub. Date: Jun. 2, 2011

(54) METHOD FOR MANUFACTURING A PHOTOVOLTAIC CELL STRUCTURE

(75) Inventors: Markus Kupich, Buchs (CH); Johannes Meier, Corcelles (CH); Stefano Benagli, Neuchatel (CH); Tobias Roschek, Wildhaus (CH)

(73) Assignee: OERLIKON SOLAR AG, TRUEBBACH, Truebbach (CH)

(21) Appl. No.: 13/056,136

(22) PCT Filed: Jul. 27, 2009
(86) PCT No.: PCT/EP09/59637

§ 371 Date: Jan. 27, 2011

Related U.S. Application Data
(60) Provisional application No. 61/085,470, filed on Aug. 1, 2008.

(51) Int. Cl. H01L 31/18

(52) U.S. Cl. 438/57; 257/E31.001

(57) ABSTRACT

In the frame of photovoltaic cell manufacturing a silicon compound layer is deposited upon a carrier structure. Manufacturing flexibility is increased on one hand by incorporating ambient air exposure of such silicon compound layer and on the other preventing deterioration of reproducibility by such ambient air exposure by enriching the surface of the addressed silicon compound layer which is to be exposed to ambient air to an oxygen enrichment.

The present invention relates to a method for manufacturing a photovoltaic cell structure having two electrodes and comprising at least one layer of silicon compound.

Definition

We understand throughout the present description and claims under “silicon compound” a material which comprises silicon. The material comprises further and additionally to silicon at least one element. Especially hydrogenated silicon as well as silicon carbide as examples fall under this definition. Further, the addressed silicon compound may be of any material structure which is apt to be applied in photovoltaic cell structure manufacturing, may especially be of amorphous or microcrystalline structure. We thereby understand the structure to be microcrystalline if the material structure comprises at least 10% Vol., preferably more than 35 Vol. % of crystallites in an amorphous matrix.

Photovoltaic solar energy conversion offers the perspective to provide for an environmentally-friendly means to generated electricity. However, at the present state, electric energy provided by photovoltaic energy conversion units is still significantly more expensive than electricity provided by conventional power stations. Therefore, the development of more cost-effective manufacturing of photovoltaic energy conversion units attracts attention in the recent years. Amongst different approaches of manufacturing low-cost solar cells, thin-film silicon solar cells combine several advantageous aspects: Firstly, thin-film silicon solar cells can be manufactured based on thin-film deposition techniques such as plasma-enhanced chemical vapor deposition (PECVD), and thus offer the perspective of synergies with known deposition techniques to reduce manufacturing costs by using experiences achieved in the past e.g. in the field of other thin-film deposition technologies, such as in the display manufacturing sector. Secondly, thin-film silicon solar cells can achieve high-energy conversion efficiencies, striving for 10% and beyond. Thirdly, the main raw materials for the manufacturing of thin-film silicon based solar cells are abundant and non-toxic.

Amongst various approaches for manufacturing thin-film silicon solar cells or solar cell structures, particularly the concept of two or multi cell stacking, also known e.g. as tandem concept, offer the perspective of achieving energy conversion efficiencies exceeding 10% due to the better exploitation of the solar irradiation spectrum compared to e.g. single cells.

Definition

We understand throughout the present description and claims as a “structure” of photovoltaic cells single photovoltaic cells in pin or nip configuration, structures of photovoltaic cells consisting of stacked cells in nip-nip or pin-pin configuration as tandem structures with two stacked cells.

Thereby, the single cells which are combined to form tandem, triple or even higher order photovoltaic cell structures do all comprise a layer of intrinsic silicon compound, as especially of intrinsic hydrogenated silicon.

Definition

We understand under “intrinsic silicon compound material” a silicon compound which is either doped neutrally, i.e. wherein negative doping is compensated by positive doping or vice versa, or such silicon compound which, as deposited, is undoped.

The addressed layers of intrinsic silicon compound may be of amorphous structure or of microcrystalline structure. If such intrinsic layer of a cell is amorphous, then the cell is named of amorphous type, a-Si, if the i-layer of a cell is of microcrystalline structure, the cell is named of microcrystalline type μc-Si. In tandem and higher order cell structures all the cells may either be a-Si or μc-Si. Customarily, tandem or higher order cell structures provide the cells of mixed type, a-Si and μc-Si, to exploit the advantages of both cell types in the photovoltaic cell structure.

A thin-film photovoltaic cell structure includes a first electrode, one or more stacked single cells in p-i-n or n-i-p structure and a second electrode. The electrodes are necessary to tap off electric current from the cell structure.

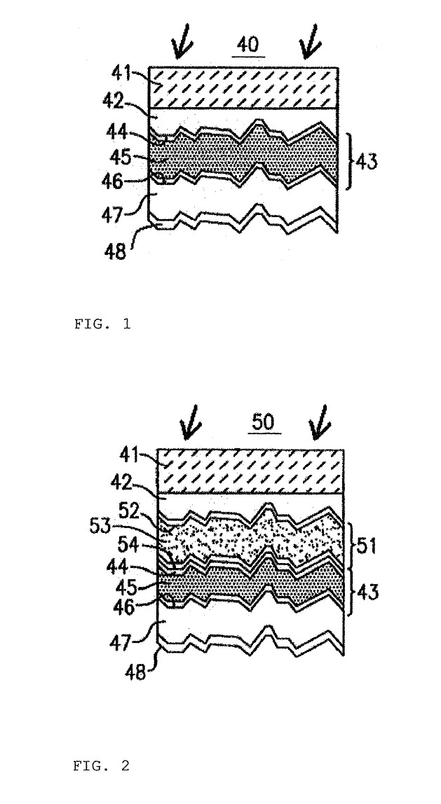

FIG. 1 shows a basic simple photovoltaic single cell 40. It comprises a transparent substrate 41, e.g. of glass, with a layer of a transparent conductive oxide (TCO) 42 deposited thereon and acting as one of the electrodes. This layer is also called in the art “Front Contact” FC. There follow the active layers of the cell 43. The cell 43 as exemplified consists in a p-i-n structure of layer 44 adjacent to the TCO which is positively doped. The subsequent layer 45 is intrinsic and the final layer 46 is negatively doped. In an alternative embodiment the layer sequence p-i-n as described may be inverted to n-i-p. Then layer 44 is n-doped and layer 46 is p-doped.

Finally, the cell structure comprises a rear contact layer 47 also called “Back Contact”, BC, which may be made of zinc oxide, tin oxide or ITO and which customarily is provided with a reflective layer 48. Alternatively, the back contact may be realized by a metallic material which may combine the physical properties of back reflector 48 and back contact 47. In FIG. 1 the arrow indicates the impinging light for illustrative purposes.

For tandem photovoltaic cell structures it is known in the art to combine an a-Si single cell having sensitivities in a shorter wavelength spectrum with a μc-Si cell, which exploits the longer wavelengths of solar spectrum. However, combinations like a-Si/a-Si or μc-Si/μc-Si or others are possible for photovoltaic and especially solar cell structures. For illustrative purposes FIG. 2 shows a photovoltaic tandem cell structure. As in the cell of FIG. 1 it comprises a substrate 41 and, as a first electrode, a layer of transparent conductive oxide TCO 44, as was addressed also named front contact FC or front electrode. The cell structure further comprises the first cell, e.g. of hydrogenated silicon 43 which latter comprises three layers 44, 45 and 46 like the addressed layers in the embodiment of FIG. 1. There is further provided a rear contact layer 47 as a second electrode and a reflective layer 48. The properties and requirements of the structure according to FIG. 2 and as described to now have already been described in context with FIG. 1. The cell structure further comprises a second cell, e.g. of hydrogenated silicon 51. Latter comprises three layers 52, 53, 54 which are respectively positively doped, intrinsic and negatively doped layers and which form the p-i-n structure of the second cell. The cell 51 may be located between front contact layer 42 and the cell 43 as shown in FIG. 2, but alternatively the two cells 43 and 51 may be inversed with respect to their order, resulting in a layer and cell structure 42, 43, 51, 47. Again for illustrative purposes the arrow indicates impinging light. Considered from the direction of incident light it is common to refer to the “top cell” which is closer to the incident light and “bottom cell”. In the example of FIG. 2 cell 51 is thus the top cell and cell 53 the bottom cell. In such tandem cell structure customarily both, cell 43 and 51 are a-Si type or cell 51 is of a-Si type and cell 43 of μc-Si type.

For industrial manufacturing photovoltaic cell structures as were addressed and exemplified above, reproducibility is an important prerequisite. A multitude of different layers have to be stacked one upon the other. Thereby, processing environment which is established for depositing one layer may be significantly different from processing environment for depositing the next following layer. Performed in one deposition chamber this necessitates a time-consuming reconditioning of the processing environment after having deposited the first addressed layer and before propagating to depositing the next following layer. Therefore, it is often preferred to perform deposition of a first layer in one layer deposition chamber, to transport the product with the addressed layer deposited to a further chamber for depositing the next layer so as to get rid of the necessity of recondition the process environment in a common chamber. Thereby, such a transport is often performed in ambient air. This simplifies the overall manufacturing plant significantly and improves flexibility of establishing mutual cooperation of various deposition equipments.

Further, it has to be considered that in the course of manufacturing photovoltaic cell structures it might be desirable to intermediately store an intermediate product of the cell structure with uncovered silicon compound layer before applying a further covering substrate or coating. This need or desire may arise when applying the additional covering is e.g. based on a process which is completely different from all the processings which were applied to manufacture the intermediate product. Thus, it might be desirable in the overall manufacturing to long-time expose the intermediate product with uncovered silicon compound layer to ambient air.

Any exposure to ambient air leads to influencing the yet uncovered surface of the product predominantly by an oxidizing effect. Therefore, one performs exposure to ambient air in the overall manufacturing process there, where such oxidizing effect does at least not harm the resulting photovoltaic characteristics of the photovoltaic cell structure or even there, where such effect of ambient air exposure improves photovoltaic cell structure characteristics. Thus, one may say that ambient air exposure of a layer surface during structure manufacturing is often highly desirable. It is e.g. known from J. Loeffler et al. “Amorphous and micromorph silicon tandem cells with high open-circuit voltage”, Solar Energy Materials and Solar Cells 87 (2005) 251-259, to introduce between depositing a wide gap i-layer of a photovoltaic cell structure and depositing a μc-Si n-layer, a first air break, and between depositing the addressed μc-Si n-layer and depositing a μc-Si p-layer a second air break.

With an eye on the influence of ambient air exposure upon the layer surface exposed it must be considered that such influence largely depends on the prevailing ambient air conditions. Thus, such exposure presents an uncontrolled processing step in opposition to processing steps which are performed in deposition chambers with accurately controlled processing environment. Introducing an uncontrolled processing step, namely the addressed exposure to ambient air, into the overall manufacturing sequence negatively influences reproducibility of the photovoltaic cell structures. It is an object of the present invention to remedy the addressed drawback.

This is achieved by the method of manufacturing a photovoltaic cell structure having two electrodes and comprising at least one layer of a silicon compound comprising
deposition of said silicon compound layer upon a carrier structure for said one silicon compound layer, resulting in one surface of the silicon compound layer resting on the carrier structure and a second surface of the silicon compound layer being uncovered,
processing the second surface of the silicon compound layer in a predetermined oxygen containing atmosphere, thereby enriching said second surface of said silicon compound layer with oxygen and
exposing said enriched second surface to ambient air.

By processing the addressed uncovered surface of the silicon compound layer in a predetermined oxygen containing atmosphere there is established a well controlled process step for the addressed surface which either makes the addressed surface substantially immune to subsequent ambient air exposure or which “overrides” the effect of ambient air exposure if such ambient air exposure has been applied before the addressed processing.

For example by unloading coated substrates from a deposition chamber into ambient air the substrates are usually still at a temperature which is significantly above ambient or room temperature. Depending on the prevailing ambient air conditions unpredictable oxidation effects occur upon the uncovered surface of the silicon layer. Such oxidation effect depends on different ambient air conditions, such as air pressure, temperature or air humidity, exposure time, especially air pressure, temperature and humidity being uncontrolled. The addressed effect further depends on the prevailing substrate temperature. If according to the present invention a processing step in an oxygen containing atmosphere is performed in a well predetermined and controlled manner, preferably before performing the step of exposing the surface to ambient air, it has been found that the remaining influence of ambient air exposure may be reduced to be neglectable.

Also an influence of ambient air exposure before establishing the addressed processing under well controlled conditions may often be overwritten by the controlled exposure step to become neglectable.

Thus, by the method according to the invention oxidation of freshly processed workpieces is accurately controlled by adjusting processing parameters, such that reproducible results for industrial production result in spite of having the respective surface exposed to ambient air.

Thereby, it should be considered that by introducing, according to the present invention, the addressed processing step it becomes possible to flexibly exploit ambient air exposure during industrial manufacturing of photovoltaic cell structures.

In one embodiment of the method according to the invention the addressed processing is performed by exposing the second surface to a predetermined gaseous atmosphere containing oxygen during a predetermined time. In a further embodiment the addressed gaseous atmosphere is kept at a pressure above ambient pressure. Further, in one embodiment the gaseous atmosphere to which the second surface is exposed during a predetermined time is kept at a temperature above ambient temperature.

Still in a further embodiment of the method according to the invention the addressed processing is performed by exposing the second surface for a predetermined time to a predetermined stream of a gas which contains oxygen.

Still in a further embodiment of the method according to the invention the addressed processing is performed by exposing the surface for a predetermined amount of time to a thermocatalytic process with oxygen containing radicals.

Still in a further embodiment of the method according to the invention, wherein the second surface is exposed to a predetermined gaseous atmosphere containing oxygen and during a predetermined time, the addressed gas is activated by a plasma discharge. Thereby and in a further embodiment the addressed plasma discharge is established in the gas of the atmosphere which contains CO₂.

Still in a further embodiment of the method according to the invention, the oxygen containing atmosphere is on vacuum pressure.

Still in a further embodiment of the method according to the invention the addressed processing of the second surface is performed by wet processing.

Still in a further embodiment of the method according to the invention a further layer is deposited upon the second surface after having been exposed to ambient air. Thereby, such further layer, in one embodiment, is of a silicon compound.

By the present invention reproducibility of photovoltaic cell structure manufacturing is significantly improved in spite of ambient air atmosphere exposure during the manufacturing of the structure.

The invention with its embodiments shall now be further exemplified. Thereby, different approaches for processing the uncovered second surface of silicon compound in the predetermined oxygen containing atmosphere are described.

In the following the carrier structure with the one silicon compound layer which is uncovered will be addressed by “workpiece”.

a) Oxidizing in oxygen containing atmosphere at elevated temperature and at ambient pressure

The workpiece is exposed to an atmosphere containing oxygen, as e.g. air, pure oxygen, a nitrogen/oxygen gas mixture, H₂O or a gas mixture containing other organic or oxygen containing compounds at ambient pressure. The temperature is kept between 50° C. and 300° C., thereby preferably between 100° C. and 200° C. The duration of the exposure is between 1 h and 10 h. The exposure of the processed workpiece can be determined as the product of exposure time (minutes) and temperature (degrees C.). This value which we call “exposure rate” has to be kept essentially between 5000 and 30,000.

If during the exposure time the temperature varies, the exposure rate may be calculated by the time integral of the temperature course.

If further the pressure is lowered or increased with respect to ambient pressure, as a generic rule, one may say that for each 10% of pressure increase or of pressure decrease the exposure rate is respectively increased or decreased by 10% compared with the exposure rate calculated for previously set pressure, e.g. ambient pressure. Thus, one may say that an exposure rate calculated for ambient pressure will vary proportionally to a variation of pressure departing from such ambient pressure.

b) Gas stream processing

A further possibility to perform the addressed processing of the workpiece is by a hot oxidizing gas stream. This may be realized by exposing the workpiece to a heated gas stream e.g. realized by a fan which is directing the hot oxidizing gas such as air onto and along the surface to be processed from the workpiece as e.g. within an oven.

c) Exposing to oxygen radicals

A further possibility to perform processing of the workpiece according to the invention is to expose the workpiece to an atmosphere in which the formation of oxygen containing radicals is enhanced by adding a source of oxygen containing radicals, e.g. a catalyst, as known to the skilled artisan in the setup of thermocatalytic deposition systems as used in so-called hot wire reactors. Here a gas mixture containing organic or oxygen containing compounds is catalytically decomposed on the surface of a catalyst and/or by secondary reaction in the gas phase.

d) Exposing to atmosphere with plasma discharge

A further possibility to perform the addressed processing of the second surface of silicon compound layer, i.e. of the workpiece, is to generate within a process chamber a plasma discharge, thereby establishing in the addressed chamber an atmosphere containing a gas or gas mixture which acts as source of oxygen radicals, e.g. O2, CO₂, H₂O or any gas mixture containing other organic or oxygen containing compounds. The plasma discharge can be realized e.g. as an Rf-, Hf-, VHF-, DC-discharge, thereby e.g. by a microwave discharge. Such processing step can directly follow the last layer deposition step, possibly in the same processing chamber. The pressure during such plasma processing can be in the range between 0.01 and 100 mbar, is preferably set to a value between 0.3 mbar and 1 mbar. The power density of the plasma is preferably selected between 5 and 2500 mW/cm² (related to the electrode surface) and is preferably selected between 15 and 100 mW/cm². Further, it is an advantage to operate the workpiece at the same temperature as was used for depositing that layer of silicon compound, the surface of which being processed. Thereby, heat-up or cool-down cycles may be avoided. The processing time for such plasma-based processing may vary between 2 sec. and 600 sec. and is preferably tailored to last between 2 sec. and 15 sec. In one example of such processing the workpieces remain in the process chamber, where the last silicon compound layer has been deposited. After such layer deposition CO₂ gas is flown into the chamber. It has been found that a flow of 0.05 to 50 standard liter per minute and per m² electrode area, thereby preferably of 0.1 to 5 standard liter per minute and per m² electrode area, are a good choice for the addressed processing. The plasma ignited and generated in the CO₂ containing gas atmosphere releases oxygen from the carbon dioxide which results essentially in carbon monoxide and oxygen radicals. The oxygen radicals interact with the silicon compound surface to be processed. A short duration of plasma processing between 2 sec. and 2 min. is established, even a shorter duration of between 2 sec. and 30 sec. The plasma energy is set to a level between 15 and 100 mW/cm² electrode surface, thereby preferably between 25 and 50 mW/cm².

Because realizing the processing step by a plasma activated oxygen containing gas atmosphere leads to short processing times and may be applied in the same processing chamber as the last silicon compound layer was deposited, the surface of which being later exposed to ambient air, this kind of realizing the addressed processing is at least today the preferred one.

Generically it should be noted that for longer lasting exposure to ambient air and in view of throughput or overall processing one can exploit a processing step which lasts longer for processing the workpiece according to the present invention, and that if only short time exposure to ambient air is established, then such processing is selected to last only short time as e.g. plasma assisted processing in oxygen containing atmosphere.

e) Wet processing

It is also possible to perform the addressed processing of the workpiece by a wet processing step. Thereby, the workpieces are exposed to such wet processing leading to a surface oxidation e.g. by a soaking or by a dipping operation of the workpieces in a vessel filled with a liquid, which leads to surface oxidation. This may be realized e.g. by a water bath, a bath in a solution comprising hydrogen peroxide, in a solution of organic solvent or alkanol or other organic or oxygen containing compounds. The duration of such wet processing depends on the composition of the liquid and its temperature. E.g. in de-ionized water at a temperature of 60° C. the respective processing lasts between 2 and 60 min., normally between 5 and 30 min.

By the present invention it becomes possible to prevent uncontrolled influence of exposing a silicon compound surface to ambient air by processing such surface in an accurately controlled manner within an oxygen containing atmosphere, be it liquid or be it gaseous.

1. A method for manufacturing a photovoltaic cell structure having two electrodes and comprising at least one layer of a silicon compound comprising
deposition of said silicon compound layer upon a carrier structure for said one silicon compound layer, resulting in one surface of said silicon compound layer resting on said carrier structure, a second surface of said silicon compound layer being uncovered,
processing the second surface of said silicon compound layer in a predetermined oxygen containing atmosphere, thereby enriching said second surface of said silicon compound layer with oxygen,
exposing said enriched second surface to ambient air.

2. The method of claim 1, wherein said processing is performed by exposing said second surface to a predetermined gaseous atmosphere containing oxygen during a predetermined time.

3. The method of claim 2, wherein said gaseous atmosphere is at a pressure above ambient pressure.

4. The method of claim 2 or 3, wherein said gaseous atmosphere is at a temperature above ambient temperature.

5. The method of claim 1, wherein said processing is performed by exposing said second surface for a predetermined time to a predetermined stream of a gas containing oxygen.

6. The method of claim 1, wherein said processing is performed by exposing said surface for a predetermined amount of time to a thermo-catalytic process with oxygen containing radicals.

7. The method of claim 2, thereby activating gas of said atmosphere by a plasma discharge.

8. The method of claim 7, said gas of said atmosphere containing CO₂.

9. The method of one of claims 2, 4 to 7, said atmosphere being on a vacuum pressure.

10. The method of claim 1, said processing being wet processing.

11. The method of one of claims 1 to 9, further comprising depositing a further layer upon said second surface after said exposing to ambient.

12. The method of claim 11, said further layer being of a silicon compound.
